(19) United States
(12) Patent Application Publication
(10) Pub. No.: US 2026/0052679 A1
(43) Pub. Date: Feb. 19, 2026

(54) SEMICONDUCTOR DEVICE AND MANUFACTURING METHOD THEREOF

(71) Applicant: NANYA TECHNOLOGY CORPORATION, New Taipei City (TW)

(72) Inventor: Tsung-Yen LIU, New Taipei City (TW)

(21) Appl. No.: 18/803,692

(22) Filed: Aug. 13, 2024

(51) Int. Cl. H10B 12/00

(52) U.S. Cl. CPC H10B 12/485; H10B 12/0335; H10B 12/315; H10B 12/34

(57) ABSTRACT

A manufacturing method of a memory device, including forming an isolation structure in a substrate to define an active region in the substrate, forming a word line structure between the isolation structure and the active region, in which the word line structure includes a word line layer and a gate dielectric layer lining the word line layer and extending along a sidewall of the active region, forming a cap layer covering the word line structure, the isolation structure, and the active region, forming a contact hole in the cap layer to expose the active region, wherein a top surface of the active region is convex, forming a bit line contact in the contact hole; and forming a bit line electrically connected with the bit line contact.

### BACKGROUND

### FIELD OF DISCLOSURE

The present disclosure relates to a semiconductor device and a manufacturing method thereof.

### DESCRIPTION OF RELATED ART

A typical DRAM memory cell incorporates a capacitor and a transistor in which the capacitor temporarily store data based on the charged state of the capacitor. A bit line is electrically connected to a source/drain region of the transistor, and a word line is electrically connected to a gate region of the transistor. The capacitor is electrically connected to the other source/drain region of the respective transistor. The resistance between different components of the memory cell should be reduced to enhance the performance of the memory cell.

### SUMMARY

It is to be understood that both the foregoing general description and the following detailed description are by examples, and are intended to provide further explanation of the disclosure as claimed.

Some embodiments of the present disclosure provide a manufacturing method of a memory device, including forming an isolation structure in a substrate to define an active region in the substrate, forming a word line structure between the isolation structure and the active region, in which the word line structure includes a word line layer and a gate dielectric layer lining the word line layer and extending along a sidewall of the active region, forming a cap layer covering the word line structure, the isolation structure, and the active region, forming a contact hole in the cap layer to expose the active region, wherein a top surface of the active region is convex, forming a bit line contact in the contact hole; and forming a bit line electrically connected with the bit line contact.

In some embodiments, the contact hole further exposes the gate dielectric layer along the sidewall of the active region.

In some embodiments, forming the contact hole includes forming a recess in the cap layer to expose a top surface of the active region and a top end of the gate dielectric layer conformally along the sidewall of the active region, removing a portion of the gate dielectric layer conformally along the sidewall of the active region through the recess, and after removing the portion of the gate dielectric layer, removing a portion of the active region, such that the top surface of the active region is higher than the top end of the gate dielectric layer conformally along the sidewall of the active region.

In some embodiments, a first etchant is used to remove the portion of the gate dielectric layer, a second etchant is used to remove the portion of the active region, and the first etchant is different from the second etchant.

In some embodiments, the first etchant is used to further remove a portion of the cap layer adjacent to the gate dielectric layer.

In some embodiments, during removing the portion of the gate dielectric layer, a top corner of the active region is etched, such that the top surface of the active region is convex.

In some embodiments, the top surface of the active region is 3-10 nm higher than the top end of the gate dielectric layer conformally along the sidewall of the active region.

In some embodiments, a width of a bottom opening of the contact hole is not less than a width of a top portion of the active region.

In some embodiments, the bit line contact is in contact with a top end of the gate dielectric layer conformally along the sidewall of the active region.

In some embodiments, a sidewall of the bit line contact is convex towards the cap layer.

Some embodiments of the present disclosure provides a memory device, includes a substrate including an active region protruding upwards, an isolation structure in the substrate and adjacent to the active region of the substrate, a word line structure between the active region of the substrate and the insolation structure, a bit line contact over the active region of the substrate, wherein a top surface of the active region of the substrate is convex towards the bit line contact, and a bit line over the bit line contact.

In some embodiments, the word line structure includes a word line layer, and a gate dielectric layer lining the word line layer and extending along a sidewall of the active region of the substrate, in which a top end of the gate dielectric layer along the sidewall of the active region of the substrate is lower than the top surface of the active region of the substrate.

In some embodiments, the bit line contact is in contact with the top end of the gate dielectric layer along the sidewall of the active region of the substrate.

In some embodiments, the top surface of the active region of the substrate is 3-10 nm higher than the top end of the gate dielectric layer along the sidewall of the active region of the substrate.

In some embodiments, the memory device further includes a cap layer over the word line structure and the isolation structure and adjacent to the bit line contact.

In some embodiments, a sidewall of the bit line contact is convex towards the cap layer.

In some embodiments, a sidewall of the cap layer is concave towards the isolation structure.

In some embodiments, a bottom surface of the bit line contact is concave towards the bit line.

In some embodiments, a width of a bottom of the bit line contact is not less than a width of a top portion of the active region of the substrate.

In some embodiments, a width of the bit line contact increases as being far away from the active region of the substrate.

### BRIEF DESCRIPTION OF THE DRAWINGS

The disclosure can be more fully understood by reading the following detailed description of the embodiment, with reference made to the accompanying drawings as follows:

FIG. 1 illustrates a circuit diagram of the memory device in some embodiments of the present disclosure.

FIG. 2 illustrates a layout view of a memory device in some embodiments of the present disclosure.

FIGS. 3-6 illustrates cross-section views of a memory device taken along line A-A’ in FIG. 2 in some embodiments of the present disclosure.

FIG. 7 illustrates a layout view of the memory device in some embodiments of the present disclosure after the contact holes in the cap layer.

FIGS. 8-9 illustrates cross-section views of a memory device taken along line A-A’ in FIG. 7 in some embodiments of the present disclosure.

### DETAILED DESCRIPTION

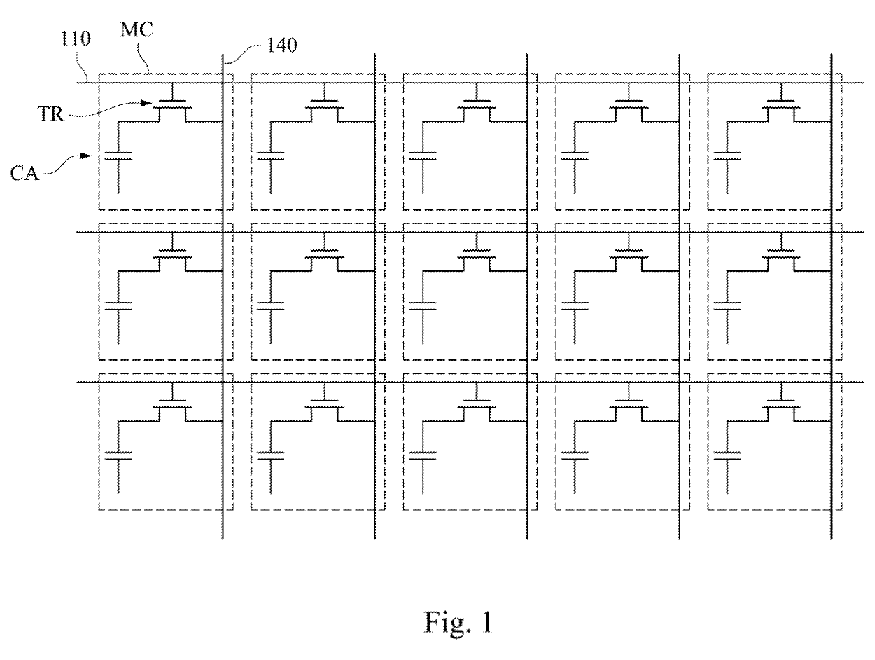

FIG. 1 illustrates a circuit diagram of the memory device in some embodiments of the present disclosure. Referring to FIG. 1, the memory device (e.g., dynamic random access memory, DRAM) may include a plurality of memory cells MC. A typical DRAM memory cell incorporates a capacitor CA and a transistor TR in which the capacitor CA temporarily store data based on the charged state of the capacitor CA. A bit line 140 is electrically connected to a source/drain region of the transistor TR, and a word line 110 is electrically connected to a gate region of the transistor TR. The capacitor CA is electrically connected to the other source/drain region of the respective transistor. The resistance of the DRAM memory cell may be reduced by increasing the contact area between two different components, such as the source/drain region of the transistor TR and the contact connected with the bit line BL.

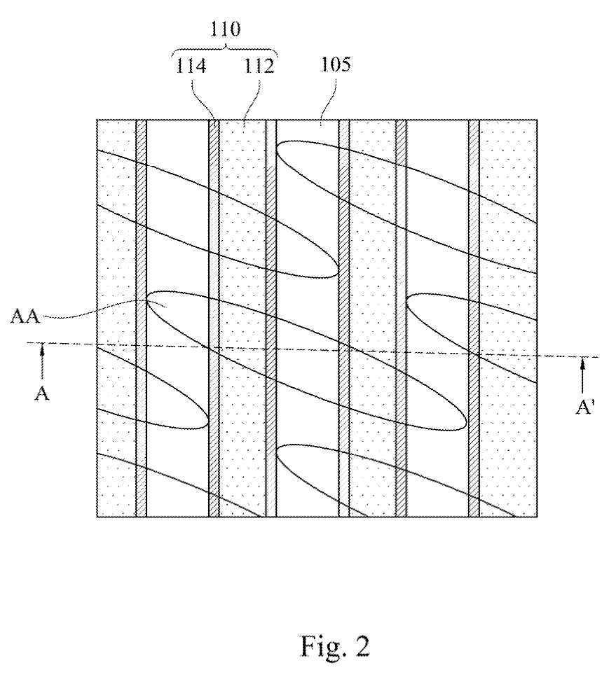

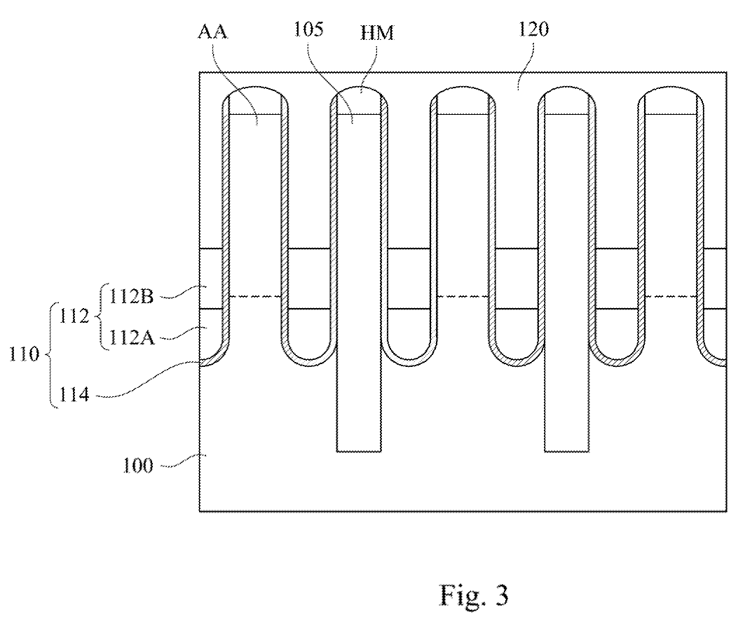

FIG. 2 illustrates a layout view of a memory device in some embodiments of the present disclosure. FIGS. 3-6 illustrates cross-section views of a memory device taken along line A-A’ in FIG. 2 in some embodiments of the present disclosure. It is noted that FIG. 2 only illustrates active regions AA, word line structures 110, and isolation structures 105 for simplicity. Referring to FIGS. 2 and 3, a substrate 100 is provided, and isolation structures 105 are formed in the substrate 100 to define active regions AA in the substrate 100. The active regions AA are protrusion portions of the substrate 100. The active regions AA and the substrate 100 excluded from the active regions AA may have different conductivity type. In some embodiments, if the active regions AA are n-type region, the substrate 100 excluded from the active regions AA are p-type region. If the active regions AA are n-type region, the substrate 100 excluded from the active regions AA are p-type region. In some embodiments, the isolation structures 105 are made of silicon oxide, silicon nitride, or the like.

Subsequently, word line structures 110 are formed between the isolation structures 105 and the active regions AA. Each of the word line structures 110 includes a word line layer 112 and a gate dielectric layer 114 lining the word line layer 112 and extending along a sidewall of the active region AA and a sidewall of the isolation structure 105. Specifically, a hard mask layer HM may be formed over the substrate 100 and the isolation structures 105. Trenches are formed in the substrate 100 by etching the substrate 100 through the hard mask HM. The gate dielectric layers 114 are formed lining the trenches. The word line layer 112 is subsequently formed in the trenches. In some embodiments, the word line layer 112 may include more than one conductive layers, such as conductive layer 112A and conductive layer 112B. The top surface of the word line layers 112 are lower than top ends of the gate dielectric layer 114, top surfaces of the isolation structures 105 and top surfaces of the active areas AA. In some embodiments, the gate dielectric layer 114 may be formed by silicon oxide. The word line layers 112 may be formed by conductive materials, such as polysilicon, metal, or combinations thereof. For example, the conductive layers 112A may be made of metal, and the conductive layers 112B may be made of polysilicon.

Subsequently, a cap layer 120 is formed filling the remaining portion of the trenches and covering the word line structures 110, the isolation structures 105, and the active regions AA. In some embodiments, the cap layer 120 is made of dielectric materials, such as silicon oxide, silicon nitride or the like.

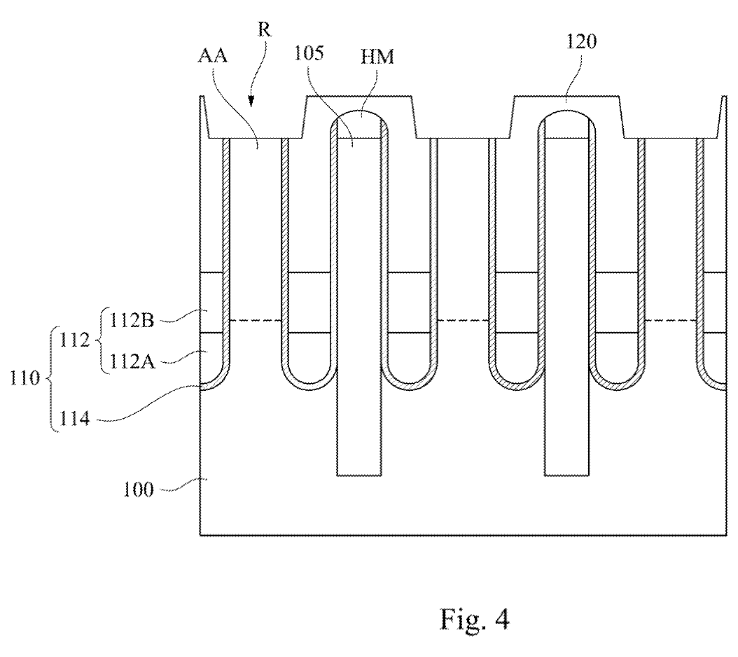

Referring to FIG. 4, recesses R are formed in the cap layer 120 to expose the top surfaces of the active regions AA and the top ends of the gate dielectric layers 114 conformally along the sidewall of the active regions AA. During forming the recesses R, the hard mask HM over the active regions AA is also removed. The width of the bottom opening of the recess R is greater than the sum of the width of the top surfaces of the active regions AA and the gate dielectric layers 114 at two sides of the active regions AA. Therefore, the bottom openings of the recesses R also expose a portion of the cap layer 120. The widths of the bottom openings of the recesses R are determined to obtain suitable profile of the contact hole formed subsequently.

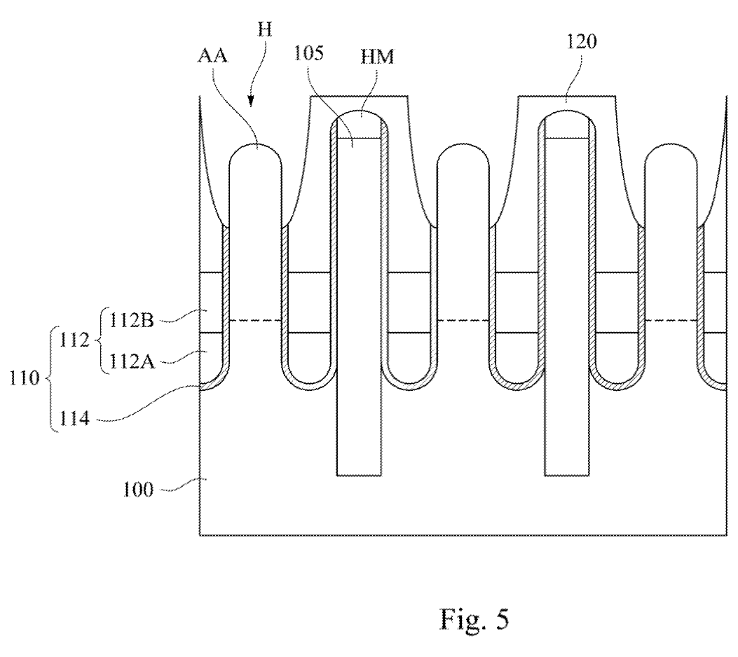

Referring to FIG. 5, a first etchant is used to remove a portion of the gate dielectric layers 114 conformally along the sidewalls of the active regions AA through the recesses R. The first etchant is used to further remove a portion of the cap layer 120 adjacent to the gate dielectric layers 114. After removing the portion of the cap layer 120 adjacent to the gate dielectric layers 114, contact holes H are formed in the cap layer 120 to expose the active regions AA and the gate dielectric layers 114 along the sidewalls of the active regions AA, and the contact holes H have concave sidewalls. The first etchant has an etching selectivity, such that the first etchant etches the gate dielectric layers 114 and the cap layer 120 faster than etches the active regions AA. Therefore, the active regions AA remain substantially intact in FIG. 5, and only top corners of the active regions AA are etched, such that the top surfaces of the active regions AA are convex.

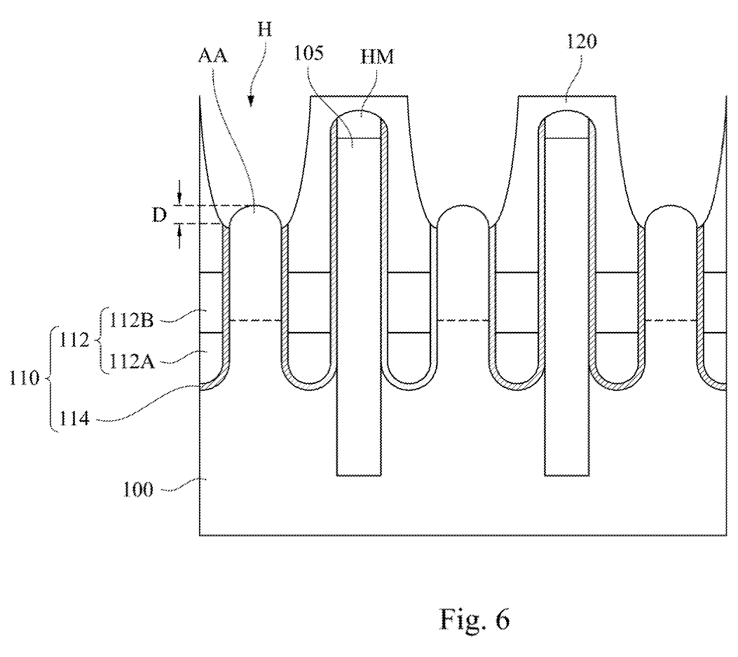

Referring to FIG. 6, after removing the portion of the gate dielectric layers 114 along the sidewalls of the active regions AA, a second etchant is used to a portion of the active regions AA, such that the top surfaces of the active regions AA is higher than the top end of the gate dielectric layers 114 conformally along the sidewalls of the active regions AA. The width of the bottom opening of the contact hole H is not less than a width of a top portion of the active region AA after the active region AA is partially etched. The second etchant is different from the first etchant. The second etchant has an etching selectivity, such that the second etchant etches the active regions AA faster than etches the gate dielectric layers 114 and the cap layer 120. In some embodiments, the top of the active regions AA are 3-10 nm higher than the top ends of the gate dielectric layers 114 conformally along the sidewalls of the active regions AA (i.e. the vertical distance D between the top of the active regions AA and the top end of the gate dielectric layer 114 conformally along the sidewalls of the active regions AA is 3-10 nm). The widths of the bottom openings of the recesses R in FIG. 5 are wider enough, so that the etchant will not mainly etches the center of the active regions AA. That is, the first etchant can easily etches the portion of the gate dielectric layers 114 along the sidewalls of the active regions AA and the portion of the cap layer 120 adjacent to the gate dielectric layers 114, and the second etchant can easily etch the peripheral portion of the active regions AA. Therefore, the top surfaces of the gate dielectric layers 114 and the peripheral portion of the active regions AA are not higher than the center of the active regions AA, and the top surfaces of the active regions AA are convex. If the top surfaces of the peripheral portion of the active regions AA are higher than the top surfaces of the center of the active regions AA, the peripheral portion of the active regions AA become sharp ends of the active regions AA. The sharp ends of the active regions AA may cause leakage current if components formed in subsequent processes (such as capacitor contact) are misaligned and in contact with the sharp ends of the active regions AA. After the contact holes H are formed, the remaining cap layers 120 still covers the word line structures 110 and the isolation structures 105, and the sidewalls of the cap layers 120 are concave towards the isolation structures 105.

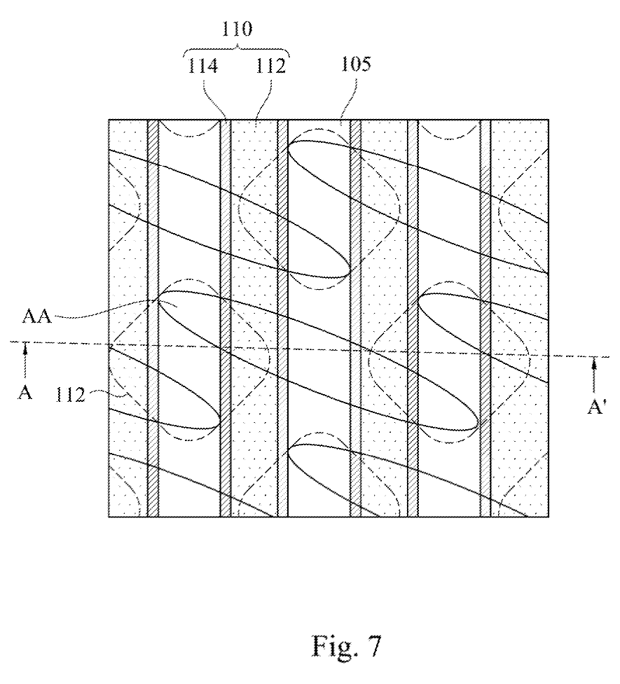

FIG. 7 illustrates a layout view of the memory device in some embodiments of the present disclosure after the contact holes H in the cap layer 120. In some embodiments, the cap layers 120 covers two ends of each of the active regions AA. The capacitor contacts (not illustrated) may be electrically connected with two ends of each of the active regions AA in the subsequent processes (for example, forming the capacitor contacts penetrating the cap layers 120). Therefore, if the capacitor contacts are misaligned, the capacitor contacts may be in contact with the sharp ends of the active regions AA and cause current leakage.

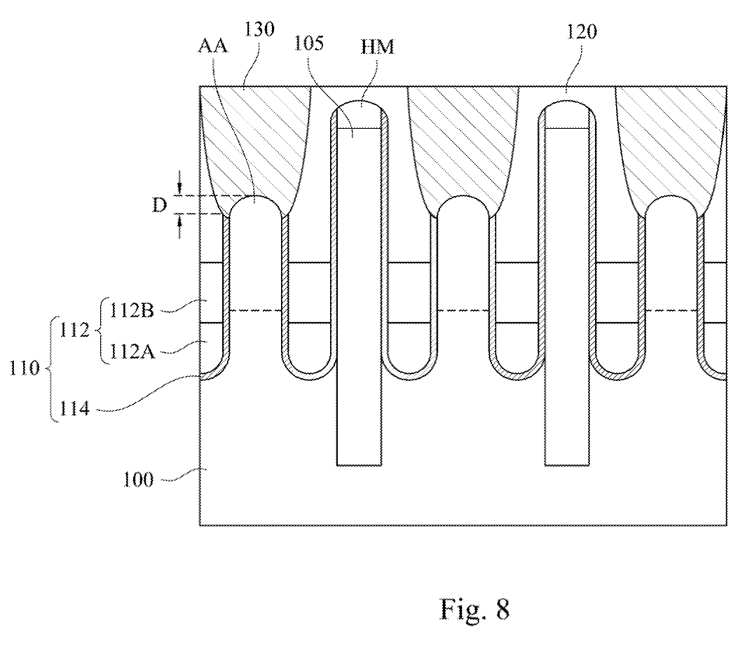

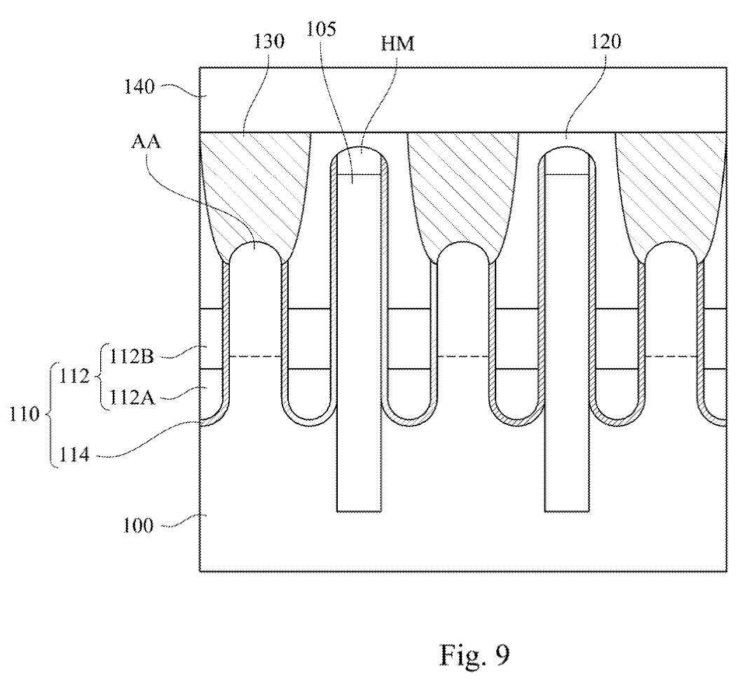

FIGS. 8-9 illustrates cross-section views of a memory device taken along line A-A’ in FIG. 7 in some embodiments of the present disclosure. Referring to FIG. 8, bit line contacts 130 are formed in the contact holes H and in contact with the exposed portion of the active regions AA in Fig, 7, and thus the bit line contacts 130 are formed between the cap layers 120. The bit line contacts 130 are in contact with the top ends of the gate dielectric layers 114 conformally along the sidewalls of the active regions AA. The sidewalls of the bit line contacts 130 are convex towards the cap layers 120. The width of the bit line contacts 130 increases as being far away from the active regions AA of the substrate 100. The bottoms of the bit line contacts 130 are concave, and the contact areas between the bit line contacts 130 and the active regions AA are increased. Therefore, the resistance between the bit line contacts 130 and the active regions AA is reduced. In some embodiments, the bit line contacts 130 may be made of conductive material, such as metal or silicon-containing material.

Referring to FIG. 9, a bit line 140 is formed over the bit line contacts 130 and the cap layers 120. The bottom surfaces of the bit line contacts 130 are concave towards the bit line 140 accordingly. The bit line 140 is electrically connected with the bit line contacts 130. In some embodiments, the bit line 140 is formed by conductive materials, such as metal.

The resulting memory device is also illustrated in FIG. 9. The memory device includes a substrate 100, isolation structure 105, word line structures 110, bit line contacts 130, cap layers 120 and a bit line 140. The substrate 100 includes active regions AA protruding upwards (such as towards the bit line 140). The isolation structure 105 are in the substrate 100 and adjacent to the active regions AA of the substrate 100. The isolation structure 105 and the active regions AA of the substrate 100 are arranged alternately in certain direction, such as FIG. 9 shown. The word line structures 110 are between the active regions AA of the substrate 100 and the isolation structure 105. The bit line contacts 130 are over the active regions AA of the substrate 100, and top surfaces of the active regions AA of the substrate 100 are convex towards the bit line contacts 130. The cap layers 120 are over the word line structures 110 and the isolation structures 105 and adjacent to the bit line contacts 130. The bit line 140 is over the bit line contacts 130 and the cap layers 120.

Each of the word line structures 110 includes a word line layer 112 and a gate dielectric layer 114. The gate dielectric layer 114 lines the word line layer 112 and extends along a sidewall of the active region AA of the substrate 100. The top end of the gate dielectric layer 114 along the sidewall of the active region AA of the substrate 100 is lower than the top surface of the active region AA of the substrate 100.

In the present disclosure, the top surfaces of the active regions AA of the substrate 100 are convex towards the bit line contacts 130. The convex top surfaces of the active regions AA of the substrate 100 may provide advantages in the present disclosure. Specifically, the interfaces between the bit line contacts 130 and the active regions AA are large when the interfaces are curved. Therefore, the resistance between the bit line contacts 130 and the active regions AA is reduced. Moreover, the convex top surfaces of the active regions AA of the substrate 100 avoid the formation of sharp ends of the active regions AA. The sharp ends of the active regions AA of the substrate 100 increase the possibility of the current leakage if there the sharp ends are in contact with other components due to the misalignments between other components (such as capacitor contact) and the active regions AA.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a memory device, comprising:
forming an isolation structure in a substrate to define an active region in the substrate;
forming a word line structure between the isolation structure and the active region, wherein the word line structure includes a word line layer and a gate dielectric layer lining the word line layer and extending along a sidewall of the active region;
forming a cap layer covering the word line structure, the isolation structure, and the active region;
forming a contact hole in the cap layer to expose the active region, wherein a top surface of the active regions is convex;
forming a bit line contact in the contact hole; and
forming a bit line electrically connected with the bit line contact.

2. The manufacturing method of claim 1, wherein the contact hole further exposes the gate dielectric layer along the sidewall of the active region.

3. The manufacturing method of claim 1, wherein forming the contact hole comprises:
forming a recess in the cap layer to expose a top surface of the active region and a top end of the gate dielectric layer conformally along the sidewall of the active region;
removing a portion of the gate dielectric layer conformally along the sidewall of the active region through the recess; and
after removing the portion of the gate dielectric layer, removing a portion of the active region, such that the top surface of the active region is higher than the top end of the gate dielectric layer conformally along the sidewall of the active region.

4. The manufacturing method of claim 3, wherein a first etchant is used to remove the portion of the gate dielectric layer, a second etchant is used to remove the portion of the active region, and the first etchant is different from the second etchant.

5. The manufacturing method of claim 4, wherein the first etchant is used to further remove a portion of the cap layer adjacent to the gate dielectric layer.

6. The manufacturing method of claim 3, wherein during removing the portion of the gate dielectric layer, a top corner of the active region is etched, such that the top surface of the active region is convex.

7. The manufacturing method of claim 3, wherein the top surface of the active region is 3-10 nm higher than the top end of the gate dielectric layer conformally along the sidewall of the active region.

8. The manufacturing method of claim 1, wherein a width of a bottom opening of the contact hole is not less than a width of a top portion of the active region.

9. The manufacturing method of claim 1, wherein the bit line contact is in contact with a top end of the gate dielectric layer conformally along the sidewall of the active region.

10. The manufacturing method of claim 1, wherein a sidewall of the bit line contact is convex towards the cap layer.

11. A memory device, comprising:
a substrate comprising an active region protruding upwards;
an isolation structure in the substrate and adjacent to the active region of the substrate;
a word line structure between the active region of the substrate and the insulation structure;
a bit line contact over the active region of the substrate, wherein a top surface of the active region of the substrate is convex towards the bit line contact; and
a bit line over the bit line contact.

12. The memory device of claim 11, wherein the word line structure comprises:
a word line layer; and
a gate dielectric layer lining the word line layer and extending along a sidewall of the active region of the substrate, wherein a top end of the gate dielectric layer along the sidewall of the active region of the substrate is lower than the top surface of the active region of the substrate.

13. The memory device of claim 12, wherein the bit line contact is in contact with the top end of the gate dielectric layer along the sidewall of the active region of the substrate.

14. The memory device of claim 12, wherein the top surface of the active region of the substrate is 3-10 nm higher than the top end of the gate dielectric layer along the sidewall of the active region of the substrate.

15. The memory device of claim 11, further comprising:
a cap layer over the word line structure and the isolation structure and adjacent to the bit line contact.

16. The memory device of claim 15, wherein a sidewall of the bit line contact is convex towards the cap layer.

17. The memory device of claim 15, wherein a sidewall of the cap layer is concave towards the isolation structure.

18. The memory device of claim 11, wherein a bottom surface of the bit line contact is concave towards the bit line.

19. The memory device of claim 11, wherein a width of a bottom of the bit line contact is not less than a width of a top portion of the active region of the substrate.

20. The memory device of claim 11, wherein a width of the bit line contact increases as being far away from the active region of the substrate.
